(19) United States
(12) Patent Application Publication
(10) Pub. No.: US 2012/0193758 A1
(43) Pub. Date: Aug. 2, 2012

(54) SEMICONDUCTOR APPARATUS AND MANUFACTURING METHOD THEREOF

(75) Inventors: Mi Hyeon Jo, Icheon-si (KR); Woong Ju JANG, Icheon-si (KR); Ki Myung KYUNG, Icheon-si (KR)

(73) Assignee: HYNIX SEMICONDUCTOR INC., Icheon-si (KR)

(21) Appl. No.: 13/219,618

(22) Filed: Aug. 27, 2011

(30) Foreign Application Priority Data
Jan. 28, 2011 (KR) 10-2011-0009010

(51) Int. Cl. H01L 29/94; H01L 21/02

(52) U.S. Cl. 257/532; 438/381; 257/E21.008; 257/E29.345

(57) ABSTRACT

A semiconductor apparatus includes a first capacitor formed in a normal cell area and including a lower electrode coupled to one end of a cell transistor, and a second capacitor formed in a dummy cell area and including a lower electrode coupled to a power terminal.

### CROSS-REFERENCES TO RELATED APPLICATION

The present application claims priority under 35 U.S.C. §119(a) to Korean application number 10-2011-0009010, filed on Jan. 28, 2011 in the Korean Intellectual Property Office, which is incorporated herein by reference in its entirety.

### BACKGROUND

1. Technical Field

The present invention relates generally to a semiconductor apparatus, and more particularly to a semiconductor apparatus and a manufacturing method thereof, which can stabilize a cell plate voltage.

2. Related Art

Recently, with the high integration of a semiconductor apparatus, since a cell size of the semiconductor apparatus decreases and an operation supply voltage also decreases, an importance of a stability of a data retention operation is growing.

FIG. 1 is a circuit diagram illustrating the structure of a memory cell of a conventional semiconductor apparatus.

Referring to FIG. 1, a memory cell of a known semiconductor apparatus includes a capacitor C for storing data information and an access transistor TR for controlling the input/output of the data information stored in the capacitor C.

The operation of the semiconductor apparatus configured as above will be described below. When a word line WL is activated in a write operation, the access transistor TR coupled to the corresponding word line WL is turned on. Then, a voltage of a bit line BL is supplied to a storage electrode 110 of the capacitor C through the access transistor TR, and the capacitor C stores charge corresponding to a value obtained by multiplying a voltage difference between the storage electrode 110 and a plate electrode 120 by dielectric constant of the capacitor C. When the voltage supplied from the bit line BL is a supply voltage, data 1 is stored in the capacitor C. When the voltage supplied from the line BL is a ground voltage, data 0 is stored therein.

When the word line WL is activated in a read operation, the charge stored in the capacitor C is supplied to the bit line BL, i.e., the capacitor C and the bit line BL share the charge. The amount of the charge of the bit line BL is detected and amplified by a bit line sense amplifier (not illustrated), so that the data stored in the capacitor C is read.

In the known semiconductor apparatus performing the above operations, a voltage supplied to the plate electrode of the capacitor C will be referred to as a cell plate voltage VCP. The cell plate voltage VCP, which generally has a value corresponding to the half of the supply voltage, serves as a reference voltage for determining the amount of charge stored in the capacitor C.

For example, in an open bit line structure, since a cell matrix in which a bit line BL is formed is different from a cell matrix in which a bit line bar /BL is formed, noise may affect the plate electrodes 120 or peripheral signal lines differently, resulting in a change in the cell plate voltage VCP.

When the cell plate voltage VCP is affected by noise, the cell plate voltage VCP may vary according to the noise, and thus a sensing margin of the bit line sense amplifier may decrease and a stability of operation of the semiconductor apparatus may deteriorate.

### SUMMARY

Embodiments of the present invention are directed to a semiconductor apparatus and a manufacturing method thereof capable of stabilizing a cell plate voltage by improving a dummy cell area.

In one embodiment of the present invention, a semiconductor apparatus comprising: a first capacitor formed in a normal cell area and including a first lower electrode coupled to one end of a cell transistor; and a second capacitor formed in a dummy cell area and including a second lower electrode coupled to a power terminal.

In another embodiment of the present invention, a semiconductor apparatus comprising: a lower electrode formed in a normal cell area and a dummy cell area; a first line coupled to the lower electrode; a first contact coupled to the first line and supplying a voltage to the first line; a dielectric layer formed over a surface of the lower electrode; and an upper electrode formed over the dielectric layer.

In another embodiment of the present invention, a method for manufacturing a semiconductor apparatus comprising the steps of: forming a first contact; forming a first line over the first contact; forming a lower electrode, which is coupled to the first line, in a dummy cell area; forming a dielectric layer over a surface of the lower electrode; and forming an upper electrode over the dielectric layer.

### BRIEF DESCRIPTION OF THE DRAWINGS

Features, aspects, and embodiments are described in conjunction with the attached drawings, in which:

FIG. 1 is a circuit diagram illustrating the structure of a memory cell of a conventional semiconductor apparatus;

FIG. 2 is a sectional view illustrating a semiconductor apparatus according to an embodiment;

FIGS. 3a to 3d are sectional views illustrating the procedure of a method for manufacturing a semiconductor apparatus according to an embodiment;

FIG. 4 is a plan view illustrating a semiconductor apparatus according to an embodiment; and

FIG. 5 is a circuit diagram illustrating a memory cell integrated in a dummy cell area of a semiconductor apparatus according to an embodiment.

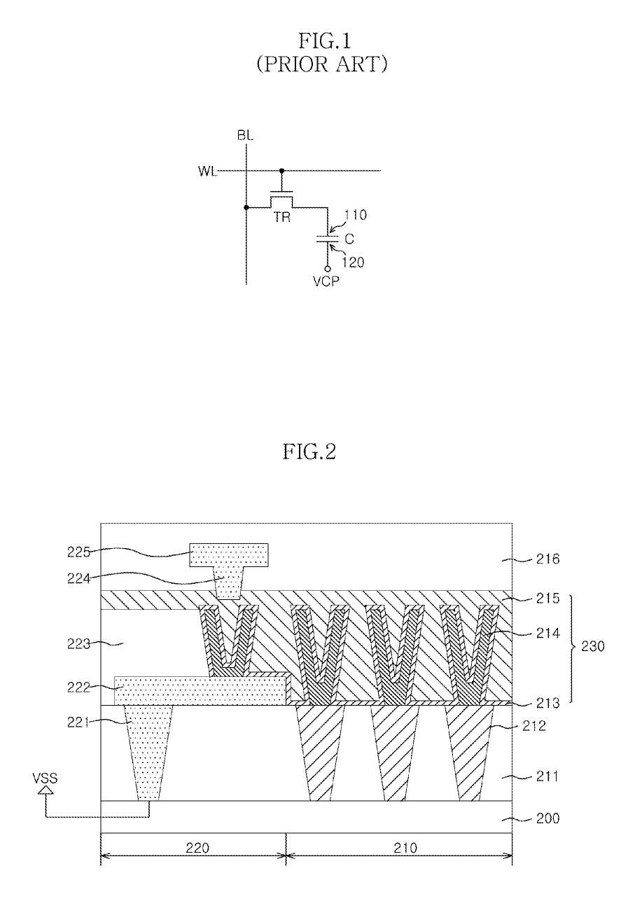

### DETAILED DESCRIPTION

Hereinafter, a semiconductor apparatus and a manufacturing method thereof according to embodiments of the present invention will be described in detail with reference to the accompanying drawings through exemplary embodiments.

FIG. 2 is a sectional view illustrating a semiconductor apparatus according to an embodiment.

Shown in FIG. 2, the semiconductor apparatus according to the embodiment includes a semiconductor substrate 200 in which a normal cell area 210 and a dummy cell area 220 are formed. The semiconductor substrate 200 includes cell arrays integrated therein. Although not illustrated in the drawing, according to an example, a lower structure, including electrodes, transistors and insulation layers, is formed on the semiconductor substrate 200, and a bit line including bit line and a bit line hard mask stacked therein is formed on the lower structure. Here, the bit line may be formed with a bit line spacer at a lateral side thereof.

In the semiconductor apparatus according to the embodiment as described above, a first insulation layer 211 is formed on the semiconductor substrate 200 including a normal cell area 210 and a dummy cell area 220. Within the inner portion of the first insulation layer 211 as described above, for example, within the inner portion of the first insulation layer 211 corresponding to the normal cell area 210, a plurality of storage node contacts 212 are formed, and within the inner portion of the first insulation layer 211 corresponding to the dummy cell area 220, one or more of first metal contact 221 may be formed. The first metal contact 221 may not be formed in the dummy cell area 220 adjacent to the normal cell area 210, but may be formed in the outermost portion of the semiconductor substrate 200 on the dummy cell area 220.

The first metal contact 221 formed as above is coupled to an external power terminal, e.g., a ground voltage VSS.

A first metal line 222 is formed on the first metal contact 221. The first metal line 222 extends to the dummy cell area 220 adjacent to the normal cell area 210, as well as the first metal contact 221. As described above, the first metal line 222 is formed to allow the ground voltage VSS supplied from the bit line to be applied to a lower electrode through the first metal contact 221, so that the area of an upper electrode 215 is enlarged and thus noise of the cell plate voltage VCP decreases. In the embodiment, the first metal contact 221 is coupled to the ground voltage VSS. However, the first metal contact 221 may be coupled to a negative voltage other than the ground voltage VSS, in other words, a voltage lower than the cell plate voltage VCP.

A second insulation layer 223 is formed on the storage node contacts 212 formed in the normal cell area 210 and the first metal line 222 formed in the dummy cell area 220, and a storage node electrode 214, that is, the lower electrode of a capacitor 230 is formed in the second insulation layer 223 of the normal cell area 210 and the dummy cell area 220. A dielectric layer 213 is formed on the surface of the lower electrode 214.

A plate electrode, that is, the upper electrode 215 is formed on the lower electrode 214 while interposing the dielectric layer 213 therebetween, so that the capacitors 230 are formed in the normal cell area 210 and the dummy cell area 220, respectively.

A third insulation layer 216 is formed on the capacitors 230, and a second metal contact 224 and a second metal line 225 are formed between the third insulation layer 216 and the capacitor 230. The second metal contact 224 and the second metal line 225 are formed on the upper electrode 215 of the dummy cell area 220 adjacent to the normal cell area 210.

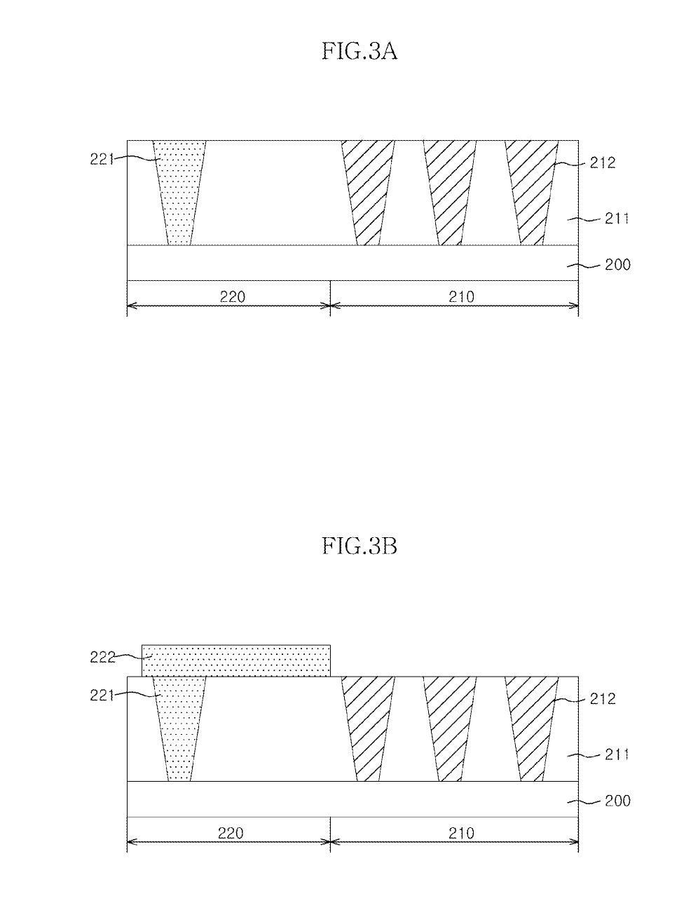

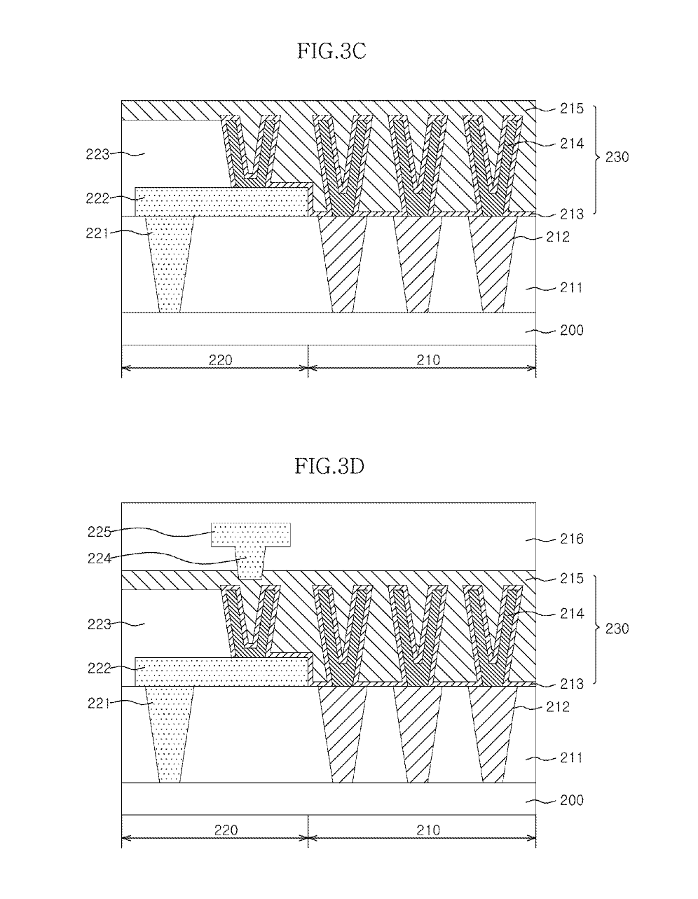

A method for manufacturing the semiconductor apparatus according to the embodiment as described above will be described with reference to FIGS. 3a to 3d.

FIGS. 3a to 3d are sectional views illustrating the procedure of the method for manufacturing the semiconductor apparatus according to the embodiment.

Referring to FIG. 3a, the first insulation layer 211 is deposited on the semiconductor substrate 200 in which normal cell area 210 and dummy cell area 220 are formed.

An etch process is performed with respect to the first insulation layer 211 to form a plurality of contact holes in the normal cell area 210, and the contact holes is filled with a conductive material, e.g., polysilicon to form the storage node contacts 212. Furthermore, an etch process is performed with respect to the first insulation layer 211 to form a first metal contact hole in the dummy cell area 220, and the first metal contact hole is filled with a conductive material to form the first metal contact 221. The first metal contact 221 may be formed in the outermost portion of the semiconductor substrate 200.

As illustrated in FIG. 3b, the first metal line 222 is formed in the dummy cell area 220 including the first metal contact 221. The first metal line 222 serves as a connection part of the ground voltage VSS or the negative voltage to be supplied from the bit line later, thereby stabilizing the cell plate voltage VCP.

As illustrated in FIG. 3c, the second insulation layer 223 is formed on a resultant structure including the first metal line 222. Here, the second insulation layer 223 may be formed of an SN oxide layer and is used to form storage node holes.

The second insulation layer 223 may be etched using a storage node mask (not illustrated) as an etch mask. The etching process is performed on the second insulation layer 223 of the normal cell area 210 and the dummy cell area 220 until the storage node contacts 212 are exposed in the normal cell area 210 and the first metal line 222 is exposed in the dummy cell area 220, thereby forming the storage node electrode, that is, the lower electrode 214. The lower electrode 214 formed in the dummy cell area 220 is formed, for example, only in a part of the dummy cell area 220 adjacent to the normal cell area 210. That is, the lower electrode 214 is not formed in the outermost portion of the semiconductor apparatus 200. The shape and the configuration of the lower electrode 214 is not limited to the embodiment, and thus the lower electrode 214 may have various shapes for improving semiconductor efficiency.

The dielectric layer 213 is formed on the surface of the lower electrode 214, and then the upper electrode 215 is formed on the lower electrode 214, thereby forming the capacitor 230. The upper electrode 215 is formed in both the normal cell area 210 and the dummy cell area 220.

As illustrated in FIG. 3d, the third insulation layer 216 is formed on a resultant structure including the upper electrode 215.

Then, the third insulation layer 216 is etched, for example, using a contact mask (not illustrated) as an etch mask until the upper electrode 215 is exposed, thereby forming a second metal contact hole (not illustrated). The second metal contact hole is filled with a conductive material to form the second metal contact 224 and the second metal line 225. Through the second metal line 225 formed as above, it is possible to apply a VDD voltage, that is, a positive voltage.

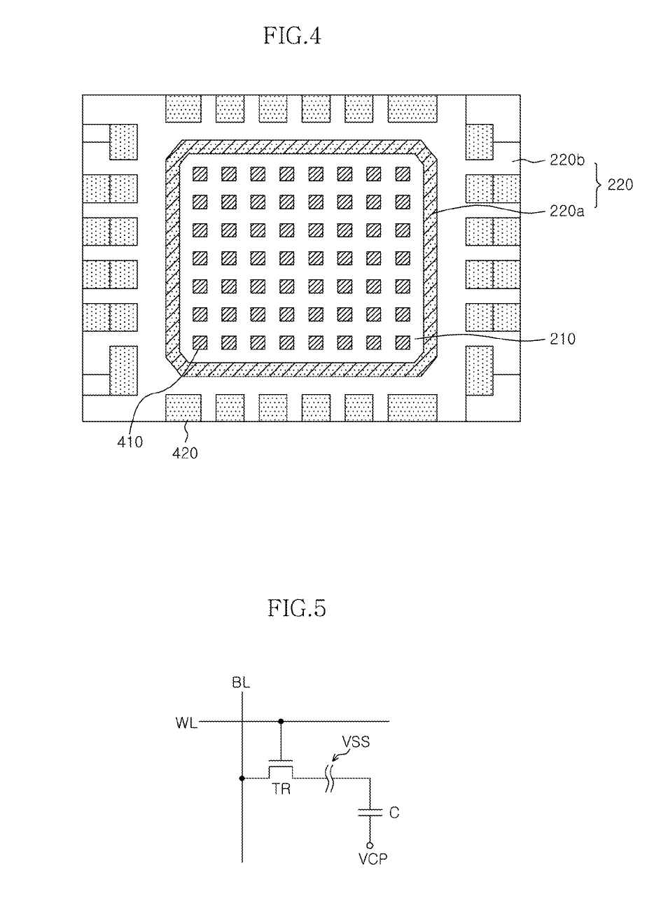

FIG. 4 is a plan view illustrating the semiconductor apparatus according to the embodiment.

Referring to FIG. 4, in the known art, a storage node layer is formed in the normal cell area and a dummy cell area adjacent to the normal cell area, and a metal line layer is formed only in a dummy cell area not adjacent to the normal cell area, that is, only in the outermost portion of the dummy cell area. However, in the semiconductor apparatus according to the embodiment, both a storage node layer 410 and a metal line layer 420 are formed in a dummy cell area 220a adjacent to a normal cell area 210. Consequently, the ground voltage VSS is applied to the floated memory cell of the dummy cell area 220, and thus the cell plate voltage VCP may become stabilized.

FIG. 5 is a circuit diagram illustrating a memory cell integrated in the dummy cell area of the semiconductor apparatus according to the embodiment.

Referring to FIG. 5, in the semiconductor apparatus according to the embodiment, it can be understood that the capacitor C of the memory cell integrated in the dummy cell area 220 receives the ground voltage VSS supplied from the bit line. Consequently, the cell plate voltage VCP of the memory cell may become stabilized.

In accordance with the semiconductor apparatus and the manufacturing method thereof according to the embodiment as described above, the metal contact and the metal line are formed in the dummy cell area and the ground voltage or the negative voltage can be received through the metal contact and the metal line, so that the influence of noise may decrease, thereby stabilizing the cell plate voltage VCP.

While certain embodiments have been described above, it will be understood to those skilled in the art that the embodiments described are by way of example only. Accordingly, the semiconductor apparatus and the manufacturing method thereof described herein should not be limited based on the described embodiments. Rather, the semiconductor apparatus and the manufacturing method thereof described herein should only be limited in light of the claims that follow when taken in conjunction with the above description and accompanying drawings.

What is claimed is:

1. A semiconductor apparatus comprising:
a first capacitor formed in a normal cell area and including a first lower electrode coupled to one end of a cell transistor; and
a second capacitor formed in a dummy cell area and including a second lower electrode coupled to a power terminal.

2. The semiconductor apparatus according to claim 1, wherein the first capacitor and the second capacitor include upper electrodes formed over each of the first and second lower electrodes, respectively, and the upper electrode of the second capacitor is connected to the upper electrode of the first capacitor.

3. The semiconductor apparatus according to claim 2, wherein the second capacitor comprises:
a first contact coupled to the power terminal;
a first line formed between an upper portion of the first contact and the first lower electrode and supplying a voltage to the first lower electrode through the first contact;
a second contact formed over the upper electrode; and
a second line formed over the second contact and supplying a voltage to the upper electrode through the second contact.

4. The semiconductor apparatus according to claim 3, wherein the first lower electrode receives one or more of a negative voltage and a ground voltage.

5. A semiconductor apparatus comprising:
a lower electrode formed in a normal cell area and a dummy cell area;
a first line coupled to the lower electrode;
a first contact coupled to the first line and supplying a voltage to the first line;
a dielectric layer formed over a surface of the lower electrode; and
an upper electrode formed over the dielectric layer.

6. The semiconductor apparatus according to claim 5, further comprising:
a second contact formed over an upper electrode of the dummy cell area; and
a second line formed over the second contact and supplying a voltage to the upper electrode through the second contact.

7. The semiconductor apparatus according to claim 5, wherein the upper electrode is formed in both the normal cell area and the dummy cell area.

8. A method for manufacturing a semiconductor apparatus, the method comprising the steps of:
forming a first contact;
forming a first line over the first contact;
forming a lower electrode, which is coupled to the first line, in a dummy cell area;
forming a dielectric layer over a surface of the lower electrode; and
forming an upper electrode over the dielectric layer.

9. The method according to claim 8, further comprising:
forming a second contact over the upper electrode formed in the dummy cell area; and
forming a second line over the second contact.

10. The method according to claim 8, wherein the step of forming the first contact comprises the steps of:
depositing a first insulation layer;
performing an etch process with respect to the first insulation layer to form a first contact hole in the dummy cell area; and
filling the first contact hole with a conductive material.

11. The method according to claim 8, wherein the step of forming the lower electrode comprises the steps of:
depositing a first insulation layer;
performing an etch process with respect to the first insulation layer to form a plurality of storage node contacts in a normal cell area;
depositing a second insulation layer over the storage node contacts and the dummy cell area; and
performing an etch process with respect to the second insulation layer to form the lower electrode in the normal cell area and a part of the dummy cell area adjacent to the normal cell area.
